(19) United States
(12) Patent Application Publication
(10) Pub. No.: US 2007/0128755 A1
(43) Pub. Date: Jun. 7, 2007

(54) Micronozzle plate and manufacturing method

(76) Inventors: Matthias Fuertsch, Gomaringen (DE); Stefan Finkbeiner, Gomaringen (DE); Christoph Schelling, Reutlingen (DE); Stefan Weiss, Tuebingen (DE); Thomas Wagner, Stuttgart (DE); Christian Maeurer, Leonberg (DE); Ines Breibach, Reutlingen (DE)

Correspondence Address: KENYON & KENYON LLP, ONE BROADWAY, NEW YORK, NY, 10004, US

(21) Appl. No.: 11/585,769

(22) Filed: Oct. 23, 2006

(30) Foreign Application Priority Data
Oct. 24, 2005 (DE) 10 2005 050 782.4

(51) Int. Cl. H01L 21/00

(52) U.S. Cl. 438/48

(57) ABSTRACT

In the manufacture of at least one passage in a silicon wafer, in a first method step, starting from a first side of the wafer, a first recess is produced in the wafer, and in a second method step, starting from a second side of the wafer, a second recess is produced in the wafer. The first recess and the second recess are produced such that together they form a passage between the first and second sides of the silicon wafer.

### CROSS-REFERENCE TO RELATED APPLICATIONS

This application claims priority to Application No. 10 2005 050 782.4, filed in the Federal Republic of Germany on Oct. 24, 2005, which is expressly incorporated herein in its entirety by reference thereto.

### FIELD OF THE INVENTION

The present invention relates to a micronozzle plate and a method for manufacturing a micronozzle plate.

### BACKGROUND INFORMATION

Different silicon-based or silicon glass-based micromechanically manufactured structures are believed to be conventional for atomizing liquids into droplets of an inhalable size (˜5 μm) in medical applications. The droplet mist may be obtained, for example, by creating a chamber which is delimited by a piezoelectrically driven diaphragm on one side and by a micronozzle plate on the other side. The chamber volume is reduced and thus a liquid in the chamber is expelled through nozzle openings in the micronozzle plate by operating the piezoelectrically driven diaphragm. The liquid is atomized in the process. Droplets of definite size may be produced via a suitable selection of nozzle geometry, chamber geometry, and piezoelectric excitation.

For manufacturing a micronozzle plate from silicon, a method is described in German Published Patent Application No. 10 2004 050 051, in which defined nozzle openings are produced in a diaphragm manufactured by KOH etching, using the silicon DRIE (Deep Reactive Ion Etch) method with the aid of high-rate anisotropic etching.

### SUMMARY

The present invention relates to a micronozzle plate and a method for manufacturing a micronozzle plate.

Oxidic nozzle structures may be produced using the method described herein. A partial oxidation of structures produced by trenching may be provided. For this purpose, areas not to be oxidized may be covered using nitride masking of the structure surfaces during the oxidation process. Subsequently structures may be hollowed via sacrificial layer etching of their cores made of semiconductor material such as Si₁₋ₓGeₓ and micronozzles may thus be obtained.

The second wafer side may be structured, e.g., by introducing a back cavity via KOH etching or another suitable etching method. The wafer may thus be eroded to the desired thickness in the area of the micronozzles.

The oxidic structures may be used as either a positive mold or a negative mold for further structuring.

Using the method described herein, it is possible to produce oxidic micronozzle structures having properties that were not manufacturable previously. Homogeneously thin-walled structures may be created over the entire height of the nozzles. The structures may have a high aspect ratio and a high degree of freedom in selecting the vertical and horizontal cross-sections over the nozzle channel depth is thus made possible.

The micronozzle plate also has a number of advantages. The nozzle walls are oxidic. The nozzle walls may have a homogeneous wall thickness over the entire nozzle channel height. The arrangement of the nozzles may allow a high degree of freedom in selecting the vertical and horizontal cross-sections. This may result in a high degree of design freedom in optimizing the microfluidic properties. For example, it is possible to manufacture the micronozzle plate with nozzle structures having a high aspect ratio. The atomizing jet characteristic may be influenceable via the selected nozzle profile.

Exemplary embodiments of the present invention are described in more detail below with reference to the appended Figures.

### BRIEF DESCRIPTION OF THE DRAWINGS

FIG. 1 illustrates a masked semiconductor substrate.

FIG. 2 illustrates the premolding of micronozzles by trenching.

FIG. 3 illustrates the molding of micronozzles made of oxide. FIG. 4 illustrates the exposure of the micronozzles made of oxide and schematically the micronozzle plate according to an example embodiment of the present invention.

FIG. 5 illustrates a method according to an example embodiment of the present invention for manufacturing a micronozzle plate.

### DETAILED DESCRIPTION

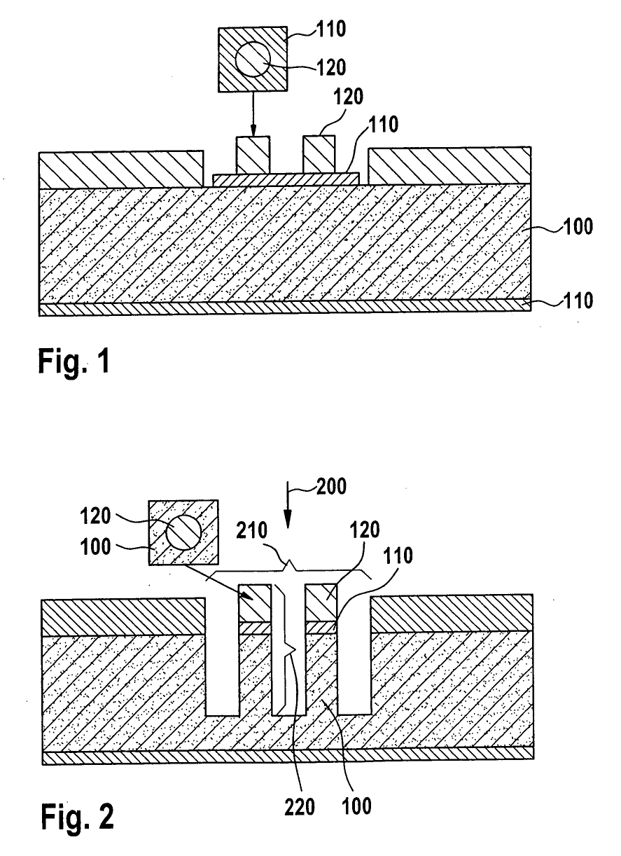

FIG. 1 illustrates a masked semiconductor substrate. To manufacture a micronozzle plate, a semiconductor substrate 100 is initially provided. Semiconductor substrate 100 may be made of silicon, germanium or a Si₁₋ₓGeₓ compound (0≦x≦1).

A first mask, e.g., a nitride layer 110, is deposited on semiconductor substrate 100 as the later oxidation mask, e.g., in an LPCVD (Low-Pressure Chemical Vapor Deposition) process. Subsequently this nitride layer 110 is structured on a first side of semiconductor substrate 100 such that it is only preserved in the area of the later micronozzles, i.e., of a later first recess.

Subsequently a second mask, e.g., a trench mask 120, is applied to the first side of semiconductor substrate 100 and on nitride layer 110. Trench mask 120 may be either a silicon oxide layer or also a pure varnish mask. The area of trench mask 120 above nitride layer 110 is structured, so that the outlines of the later micronozzles are established. For this purpose, the trench mask is removed in this area around the later micronozzles down to nitride layer 110.

The state of the wafer after structuring trench mask 120 is illustrated in FIG. 1. FIG. 1 also illustrates a sectional view and the top view onto the area of a later micronozzle for this purpose.

FIG. 2 illustrates the premolding of micronozzles by trenching. For this purpose, the contours of the later micronozzles are produced using a trench process 200, e.g., a DRIE process or a Bosch process, directed to the first side of the masked semiconductor substrate. As an option, the remaining nitride layer 110 may be initially structured separately by removing the exposed areas of nitride layer 110 not protected by trench mask 120 arranged thereon. As a result of trench process 200, trenches are produced on the first side of the wafer to a certain depth of semiconductor substrate 100, and a first recess 210 is obtained in which columns 220 are arranged as premolds of micronozzles. FIG. 2 again illustrates a sectional view of the wafer and a top view onto the area of a later micronozzle for this purpose. As illustrated, the columns include, in a layered structure, semiconductor substrate 100 on the bottom, nitride layer 110 thereon, and trench mask 120 thereon.

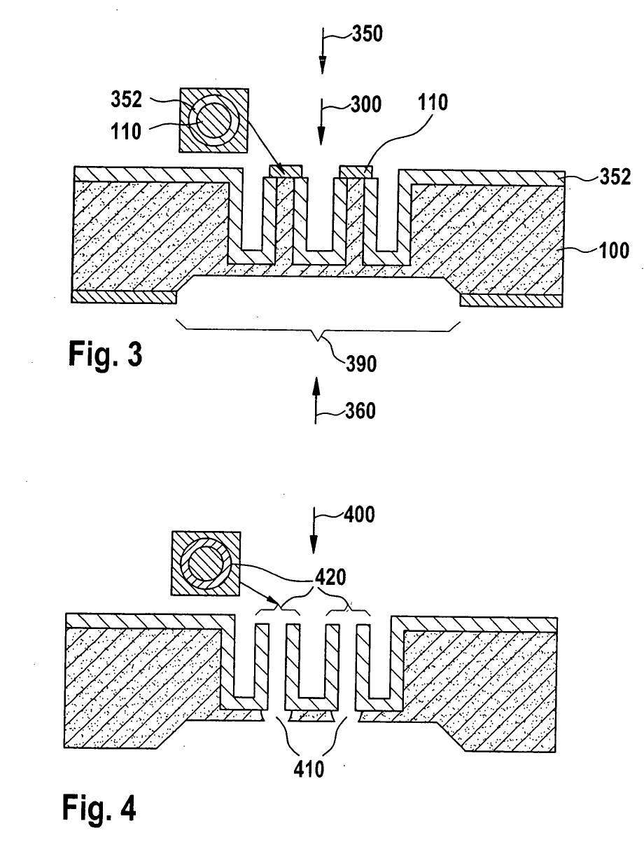

FIG. 3 illustrates the molding of micronozzles made of oxide. For this purpose, the wafer from FIG. 2 is subjected to a plurality of consecutive process steps. First, trench mask 120 is removed 300. Trench mask 120 is removed 300, for example, by gas phase etching or a BOE (Buffered Oxide Etch) process if trench mask 120 is an oxide mask, or by devarnishing, for example in oxygen plasma, if trench mask 120 is a varnish mask. Thereafter the wafer is thermally oxidized 350, and a thermal oxide layer 352 is formed by surface oxidation of the accessible Si₁₋ₓGeₓ areas of semiconductor substrate 100. The remaining nitride layer 110, which represents nitride covers on the raised structures or columns, has the role of an oxidation mask. Remaining nitride layer 110 determines inaccessible areas, e.g., on the top of the columns, and thus prevents thermal oxidation on their surfaces. As a result, the walls of the micronozzles are also manufactured from the accessible surfaces of the columns.

Optionally, a second side of semiconductor substrate 100, opposite the first side, may now be structured. For this purpose, the nitride on the back is masked and opened with the aid of an etching step. The exposed area of semiconductor substrate 100 is subsequently etched on the second side of the wafer using KOH wet etching or another suitable etching process. As a result of this etching 360, a recess 390 is obtained in semiconductor substrate 100. Recess 390 on the second side is arranged opposite the area of the later micronozzles on the first side. The mask is finally removed. The intermediary state achieved is illustrated in FIG. 3.

FIG. 4 illustrates the exposure of the micronozzles made of oxide and schematically the micronozzle plate. For this purpose, remaining silicon nitride 110 is removed from the front of the wafer in a dry etch process, for example. The entire surface of the wafer is covered with thermal oxide on the first side except the surfaces of the raised structures previously covered by nitride, where semiconductor substrate 100 is exposed and forms a sacrificial layer for the subsequent process step. The remaining solid residual silicon core is etched out of the columns using selective etching 400 of the semiconductor substrate 100 against thermal oxide 352. This may take place, for example, in a dry etching process using CIF₃. While silicon is removed by etching 400, thermal oxide 352 remains unaffected. As a result, a passage 410 and thus an access from the first side to the opposite second side of semiconductor substrate 100 is created. Hollow structures representing micronozzles 420 made of oxide remain on passage 410 made of a homogeneously thick oxide, e.g., thermal oxide 352. The micronozzle plate illustrated schematically is thus created.

Optionally, any further layers may be subsequently deposited. The oxide walls are thereby reinforced or used as a negative mold for further structuring.

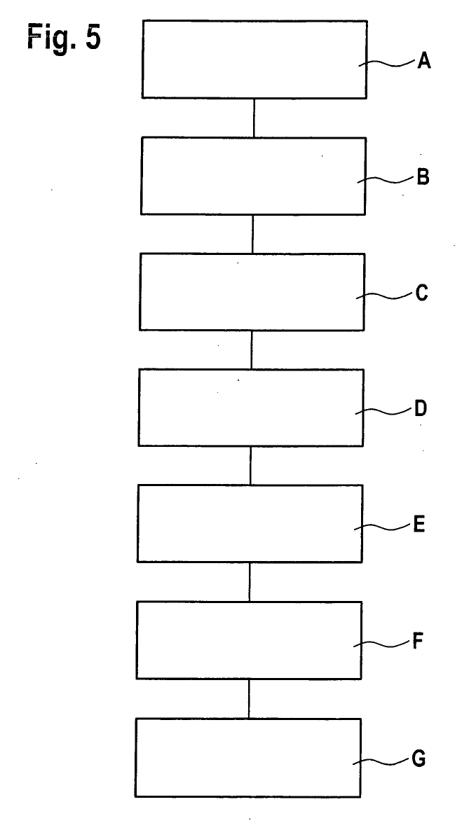

FIG. 5 schematically illustrates a method according to an example embodiment of the present invention for manufacturing a micronozzle plate including: (A) applying a first mask 110 on a first side of a semiconductor substrate 100; (B)applying a second mask 120 on first mask 110 and semiconductor substrate 100; (C) trench etching 200 of semiconductor substrate 100 through second mask 120 to a certain depth;, (D) removing 300 of second mask 120; (E) thermal oxidation 350 of semiconductor substrate 100 through first mask 110 and thus forming a thermal oxide 352 on the first side; (F) removing first mask 110 from semiconductor substrate 100; (G) etching 400 of semiconductor substrate 100 selectively with respect to thermal oxide 352 from the first side to an opposite second side and thus exposing micronozzles 420.

Semiconductor substrate 100 and first mask 110 may be trench etched 200 through second mask 120.

A recess 390 may be etched 360 on the second side to make semiconductor substrate 100 thinner in the area of micronozzles 420. Etching step 360 of recess 390 may take place after manufacturing step (A) at any point in the overall manufacturing process.

The exemplary embodiments described above may be combined in any desired manner.

What is claimed is:

1. A method for manufacturing a micronozzle plate, comprising:
applying a first mask on a first side of a semiconductor substrate;
applying a second mask on the first mask and the semiconductor substrate;
trench etching the semiconductor substrate through the second mask to a certain depth;
removing the second mask;
thermally oxidizing the semiconductor substrate through the first mask and thus forming a thermal oxide on the first side;
removing the first mask from the semiconductor substrate; and
etching the semiconductor substrate from the first side to an opposite second side and thus exposing micronozzles made of thermal oxide.

2. The method according to claim 1, wherein, in the trench etching, the first mask is also trench etched through the second mask.

3. The method according to claim 1, further comprising machining the semiconductor substrate on the second side.

4. The method according to claim 3, further comprising, after applying the first mask, etching a recess on the second side to make the semiconductor substrate thinner in an area of the micronozzles.

5. A micronozzle plate, comprising:
a semiconductor substrate including at least one passage in the semiconductor substrate, access from a first side to an opposite second side of the semiconductor substrate being provided by the passage;
a micronozzle arranged on the first side of the semiconductor substrate at the passage, the micronozzle being made of an oxide.

6. The micronozzle plate according to claim 5, wherein a first recess is arranged on the first side of the semiconductor substrate, at least one passage is arranged in the semiconductor substrate in the first recess, the micronozzle arranged in the first recess at the passage.

7. The micronozzle plate according to claim 5, wherein a layer of the oxide is arranged on the first side of the semiconductor substrate.

8. The micronozzle plate according to claim 6, wherein a second recess is arranged on the second side of the semiconductor substrate in an area of the passage.

9. The micronozzle plate according to claim 5, wherein the semiconductor substrate is made of at least one of (a) silicon, (b) germanium and (c) a Si₁₋ₓGeₓ compound.
